(19) United States
(12) Patent Application Publication
(10) Pub. No.: US 2005/0181756 A1
(43) Pub. Date: Aug. 18, 2005

(54) Wireless digital music player

(76) Inventor: Chung-Hung Lin, Syuejia Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/778,232

(22) Filed: Feb. 17, 2004

(51) Int. Cl. H04Q 7/20; H04M 11/00; H04B 1/00; H04B 1/06; H05K 11/00

(52) U.S. Cl. 455/344; 455/130

(57) ABSTRACT

A wireless digital music player has a support base, a portable storage device having digital music and audio data stored therein, and a player; the portable storage device and the player are fitted to the support base; the player has a control circuit capable of reading the music and audio data stored in the portable storage device, and has an emission circuit electrically connected to an output terminal of the control circuit for transmitting the music and audio data wirelessly at an intended frequency; thus, a radio can play the music and audio data after it is tuned to the same frequency as the emission circuit of the player to receive radio signals transmitted from the emission circuit.

### BACKGROUND OF THE INVENTION

1. Field of the Invention

The present invention relates to a wireless digital music player, more particularly one, which has a player and a portable storage device having digital music stored therein; the player has a control circuit capable of reading the music in the storage device, and has an emission circuit electrically connected to an output terminal of the control circuit for transmitting the music wirelessly at an intended frequency; thus, a radio can play the music after it is tuned to the same frequency as the emission circuit to receive radio signals from the emission circuit.

2. Brief Description of the Prior Art

There are a wide variety of music and sound playing equipments, e.g. MP3 player and CD (compact disk) player, available in the market for satisfying different consumers' needs.

MP3 players are specially provided for playing MP3 music with. The complete name of MP3 is MPEG (Movie Picture Experts group) 1 Layer 3, which belongs to the MPEG-1 layer. And, the purpose of developing MP3 is to reduce the amount of load consumed in media transmission while the quality of the media is maintained.

It is a main object of the present invention to provide a wireless multimedia player, which is distinguishable from currently available players, such that consumers have one additional choice.

### SUMMARY OF THE INVENTION

The wireless digital music player of the present invention includes a support base, a portable storage device having digital music and audio data stored therein, and a player. The portable storage device and the player are fitted to the support base. The player has a control circuit capable of reading the music and audio data stored in the portable storage device, and has an emission circuit electrically connected to an output terminal of the control circuit for transmitting the music and audio data wirelessly at an intended frequency. Thus, a radio can play the music and audio data after it is tuned to the same frequency as the emission circuit to receive radio signals transmitted from the emission circuit.

### BRIEF DESCRIPTION OF THE DRAWINGS

The present invention will be better understood by referring to the accompanying drawings, wherein:

FIG. 1 is a perspective front view of the first embodiment of a wireless digital music player in the present invention,

FIG. 2 is a partial perspective rear view of the first embodiment in the present invention,

FIG. 3 is a circuit block diagram of the first embodiment,

FIG. 4 is another circuit block diagram of the first embodiment,

FIG. 5 is a perspective view of the second embodiment of a wireless digital music player in the present invention,

FIG. 6 is a circuit block diagram of the second embodiment,

FIG. 7 is a perspective view of the third embodiment, and

FIG. 8 is a circuit block diagram of the third embodiment.

### DETAILED DESCRIPTION OF THE PREFERRED EMBODIMENTS

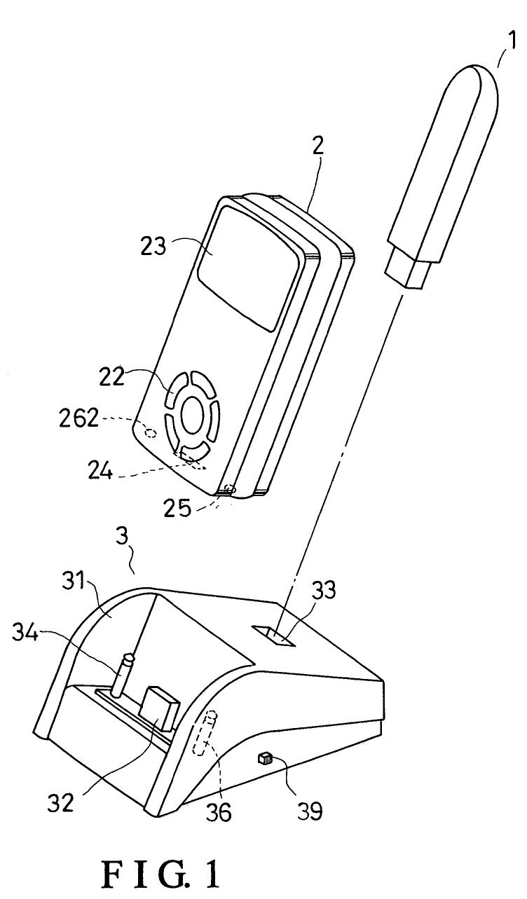

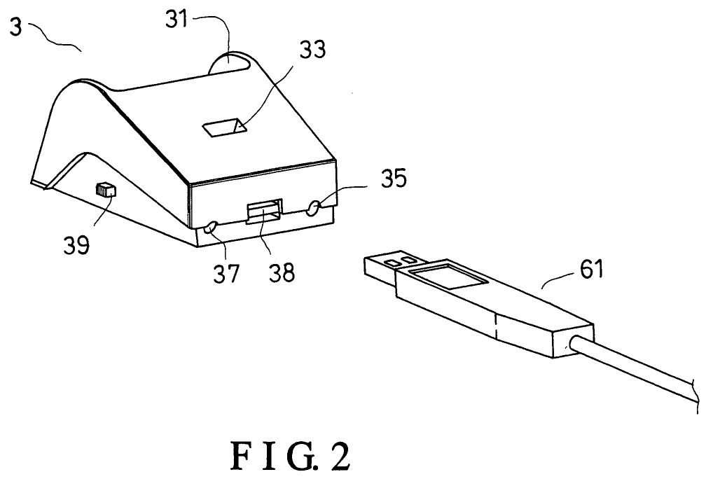

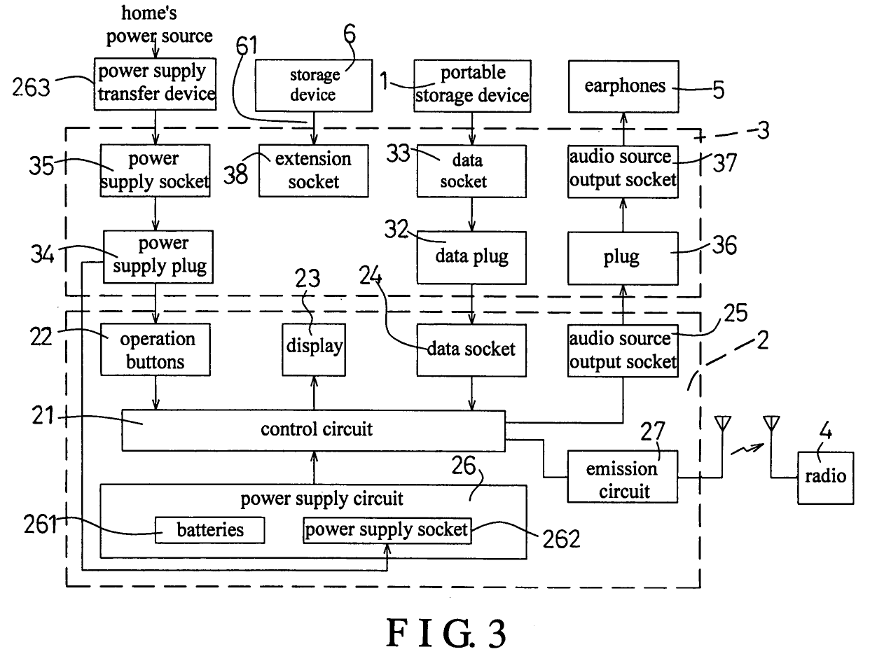

Referring to FIGS. 1 to 3, a first embodiment of a wireless digital music player in the present invention includes a portable storage device 1, a player 2, and a support base 3.

The portable storage device 1 is provided for storing digital music and audio data therein, and can be portable a hard disk, flash disk, card reader etc.

The player 2 has a control circuit 21 inside, several operation buttons 22 electrically connected to the control circuit 21, a display 23, a data socket 24, an audio source output socket 25, and a power supply circuit 26. The control circuit 21 is electrically connected to the power supply circuit 26 such that power can be supplied thereto. The power supply circuit 26 can be powered with batteries 261 or electrically connected with a power supply socket 262 fitted on a lateral side of the player 2 such that it can be powered through a power supply transfer device 263, which is connected to the power supply socket 262 as well as a home's power source. An emission circuit 27 is electrically connected to an output terminal (not shown) of the control circuit 21 such that audio source signals such as music and sound can be transmitted from the player 2 at an intended frequency. The control circuit 21 has a micro-controller as the main part, which can control operation of the circuit 21 with the help of programs prerecorded therein, and which can directly read music and audio files in the portable storage device 1. The operation buttons 22 are provided for choosing an operational function as well as adjusting the emission frequency of the emission circuit 27 with. The display 23 is electrically connected to the control circuit 21 for displaying operation-related information and the emission frequency, and can be an LCD or an LED monitor. The data socket 24 is provided for the portable storage device 1 to be connected thereto, and can be an USB socket. The emission circuit 27 is a digital frequency modulated emission circuit, and is activated and controlled by means of the control circuit 21 such that audio source signals such as music and sound are transmitted at an intended frequency.

The support base 3 has a holding cavity 31 for the player 2 to be inserted therein. The support base 3 has a data plug 32 in the holding cavity 31 for the data socket 24 of the player 2 to be connected thereto, and has a data socket 33 thereon for the portable storage device 1 to be connected thereto, which data socket 33 is electrically connected to the data plug 32. Furthermore, a power supply plug 34 is provided in the holding cavity 31 for allowing the power supply socket 262 of the player 2 to be connected thereto, and a power supply socket 35 is fitted on the support base 3 and electrically connected to the power supply plug 34 while the power supply transfer device 263 is connected to both the power supply socket 35 and a home's power source; thus, power of home's power source can be provided to the power supply circuit 26 through the power supply transfer device 263. The support base 3 has a plug 36 in the holding cavity 31 for the audio source output socket 25 of the player 2 to be connected thereto, and has an audio source output socket 37 thereon, which is electrically connected to the plug 36, and to which a set of earphones 5 can be connected such that music and sound from the player 2 is heard through the earphones 5. In addition, the support base 3 has an extension socket 38 thereon, which is connected to the data socket 33; thus, a cable 61 can be connected to both another storage device 6 and the extension socket 38 for allowing music and audio data to be transferred from the storage device 6 to the portable storage device 1; the storage device 6 can be computers, MP3 players or other equipments capable of storing music and sound such as PDA. The support base 3 further has a switching member 39, by means of which the player 2 can be switched to a playing function and a saving function; the player 2 will read and play data in the portable storage device 1 under the playing function, and will have data transferred from the storage device 6 to the portable storage device 1 under the saving function.

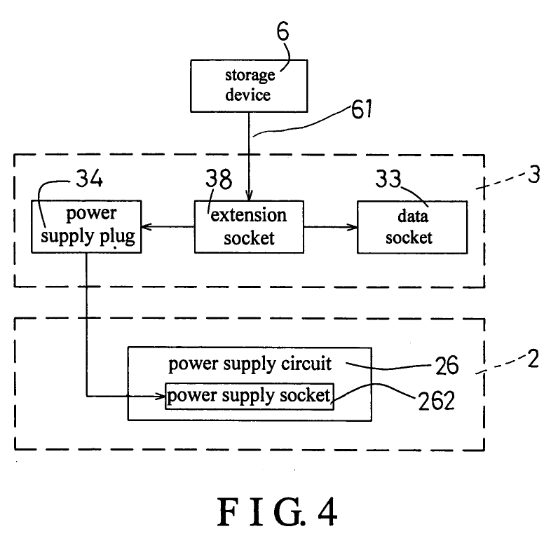

Referring to FIG. 4, besides being connected to the data socket 33, the extension socket 38 is connected to the power supply plug 34 such that power can be supplied from the storage device 6 to the power supply circuit 26 of the player 2 through both the extension socket 38 and the power supply plug 34 when the storage device 6 is connected to the extension socket 38 with the cable 61, and used as the source of music and audio data.

To use the present wireless music player, first the player 2 and the portable storage device 1 are connected to the support base 3, the switching member 39 is switched to the playing function, and the operation buttons 22 are operated to choose an operational function and adjust emission frequency of the emission circuit 27; thus, the operational function and the emission frequency are shown on the display 23. Then, the control circuit 21 of the player 2 will read and process music and audio data in the portable storage device 1, and transmit radio signals with the emission circuit 27, which radio signals are received by means of a radio 4; thus, music and sound are played through the radio 4. Earphones 5 can be connected to the audio source output socket 37 such that music and sound are heard through the earphones 5 instead.

After the cable 61 is connected to both the storage device 6 and the portable storage device 1, the switching member 39 is switched to the saving function such that music and audio data are transferred from the storage device 6 to the portable storage device 1.

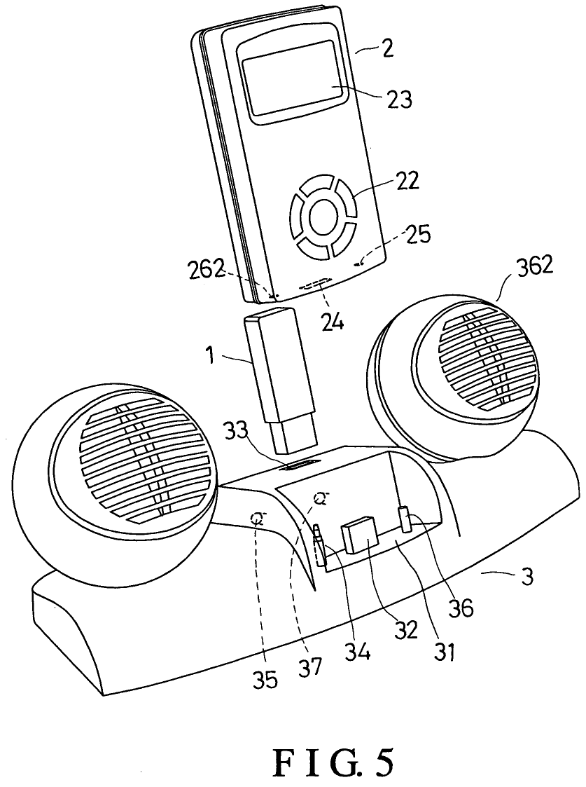

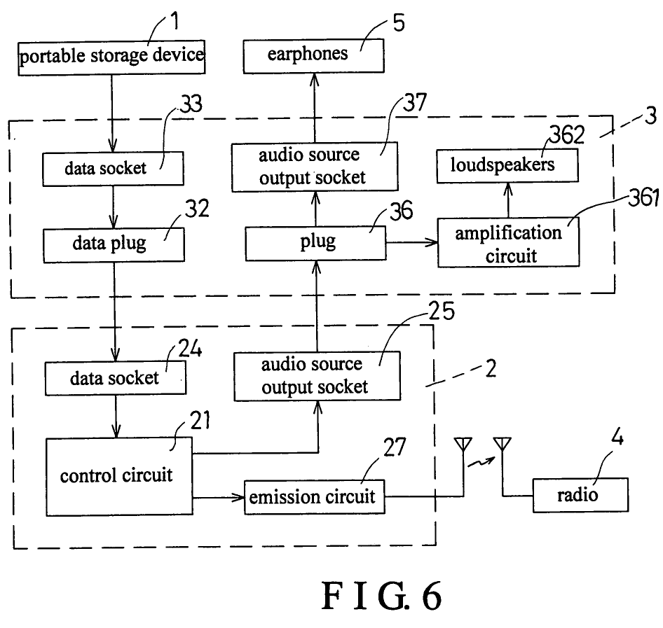

Referring to FIGS. 5 and 6, in a second embodiment of the present invention, in addition to the earphones 5 as well as both the emission circuit 27 and the radio 4 for playing music and sound with, the present digital player is equipped with an amplification circuit 361, and loudspeakers 362; the amplification circuit 361 is electrically connected to the plug 36 of the support base 3 while the loudspeakers 362 are fitted to two sides of the support base 3, and electrically connected to output terminals of the amplification circuit 361. Thus, music and audio signals are transmitted from the player 2 to the amplification circuit 361 via the plug 36, and amplified and transmitted to the loudspeakers 362 to be heard by means of the amplification circuit 361.

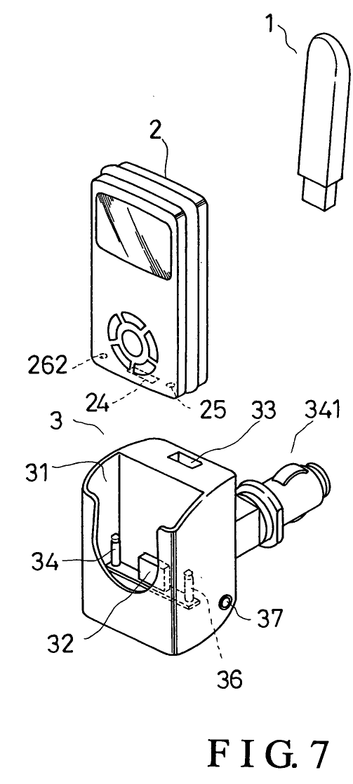

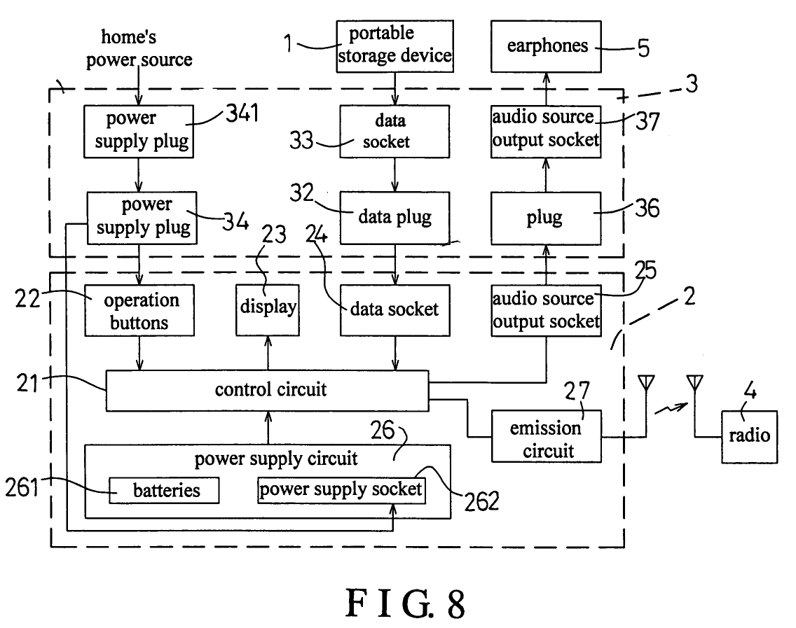

Referring to FIGS. 7 and 8, in a third embodiment of the present invention, a power supply plug 341 for use in automobiles is fitted on the support base 3, and electrically connected to the power supply plug 34 of the support base 3 such that the present music player can be used in an automobile with the power supply circuit 26 being provided with power of the automobile.

From the above description, it can be easily understood that the present invention has the following advantages:
1. When the player 2 and the portable storage device 1 are connected to the support base 3, the control circuit 21 of the player 2 will read and process music and audio data in the portable storage device 1, and the emission circuit 27 will transmit radio signals with an intended channel. Thus, after the radio 4, an ordinary FM radio, is tuned to the same channel as the emission circuit 27, the radio signals are received by the radio 4, and in turns, music and sound are played through the devices of the radio 4 and with stereophonic effects and high sound quality.
2. The users can store their favorite music and audio data with the portable storage device 1.
3. The present player will be steady on a desk with the player 2 and the portable storage device 1 being fitted to and supported on the support base 3 therefore it is convenient to use indoors.
4. The support base 3 allows connection of storage devices, e.g. computers, MP3 players, and PDA, thereto therefore music and audio data can be transferred from the storage devices to the portable storage device 1.
5. The second embodiment of the invention can also play music directly through the loudspeakers 362 after the player 2 and the portable storage device 1 are connected to the support base 3.
6. The present player, as shown in FIG. 7, can also be used in an automobile with the power supply circuit 26 being provided with power of the automobile.

1. A wireless digital music player, comprising
a support base;
a portable storage device fitted to the support base; the portable storage device having digital music and audio data stored therein; and
a player fitted to the support base; the player having a control circuit inside for reading the digital music and audio data stored in the portable storage device; the player having a data socket electrically connected to the control circuit; the player having a power supply circuit electrically connected to the control circuit for supplying power to the control circuit; the player having an emission circuit electrically connected to an output terminal of the control circuit for transmitting the music and audio data wirelessly at an intended frequency;
the support base having a holding cavity for the player to be inserted therein; the support base having a data plug in the holding cavity for the data socket of the player to be connected thereto; the support base having a data socket electrically connected to the data plug thereof for the portable storage device to be connected thereto;
thereby being capable of making a radio play the music and audio data of the portable storage device after the radio is tuned to a same frequency as the emission circuit of the player to receive radio signals transmitted from the emission circuit.

2. The wireless digital music player as claimed in claim 1, wherein the portable storage device is a portable hard disk.

3. The wireless digital music player as claimed in claimed 1, wherein the portable storage device is a flash disk.

4. The wireless digital music player as claimed in claimed 1, wherein the control circuit has a micro-controller as a main part, which is used for controlling operation of the circuit with help of programs prerecorded therein as well as for directly reading music and audio files in the portable storage device.

5. The wireless digital music player as claimed in claimed 1, wherein the emission circuit is a digital frequency modulation emission circuit.

6. The wireless digital music player as claimed in claimed 1, wherein the player has a plurality of operation buttons, and a display thereon; the operation buttons being electrically connected to the control circuit for choosing an operational function and adjusting emission frequency of the emission circuit with; the display being electrically connected to the control circuit for displaying operation-related information and the emission frequency.

7. The wireless digital music player as claimed in claimed 1, wherein batteries are used on the power supply circuit.

8. The wireless digital music player as claimed in claimed 1, wherein the player has a power supply socket fitted thereon and electrically connected to the power supply circuit thereof while the support base has a power supply plug in the holding cavity thereof for connection with the power supply socket of the player, and has a power supply socket electrically connected to the power supply plug thereof; a power supply transfer device being connected to the power supply socket of the support base such that power of a home's power source can be provided to the power supply circuit through the transfer device.

9. The wireless digital music player as claimed in claimed 1, wherein the player has an audio source output socket fitted thereon and electrically connected to an output terminal of the control circuit while the support base has a second plug in the holding cavity thereof, an amplification circuit electrically connected to the second plug, and loudspeakers fitted to the support base as well as electrically connected to the amplification circuit; the second plug of the support base being electrically connected to the audio source output socket of the player such that music and audio signals are amplified with the amplification circuit, and played through the loudspeakers.

10. The wireless digital music player as claimed in claimed 1, wherein the player has an audio source output socket fitted thereon and electrically connected to an output terminal of the control circuit while the support base has a second plug in the holding cavity thereof as well as an audio source output socket fitted thereon and electrically connected to the second plug for a set of earphones to be connected thereto.

11. The wireless digital music player as claimed in claimed 1, wherein the player has a power supply socket electrically connected to the power supply circuit thereof while the support base has a first power supply plug for connection with the power supply socket of the player, and has a second power supply plug electrically connected to the first power supply plug thereof, which second power supply plug can be connected to power source in an automobile.

12. The wireless digital music player as claimed in claimed 11, wherein the player has an audio source output socket fitted thereon and electrically connected to an output terminal of the control circuit while the support base has a second plug in the holding cavity thereof as well as an audio source output socket fitted thereon and electrically connected to the second plug for a set of earphones to be connected thereto.

13. The wireless digital music player as claimed in claimed 1, wherein the support base has an extension socket fitted thereon and electrically connected to the data socket thereof, and a cable is connected to both a second storage device and the extension socket for allowing music and audio data to be transferred from the second storage device to the portable storage device.

14. The wireless digital music player as claimed in claimed 1, wherein the player has a power supply socket fitted thereon and electrically connected to the power supply circuit thereof while the support base has a power supply plug in the holding cavity thereof for connection with the power supply socket of the player, and has an extension socket fitted thereon; the extension socket being electrically connected to the data socket of the support base such that when a cable is connected to both a second storage device and the extension socket, music and audio data can be transferred from the second storage device to the portable storage device; the extension socket being electrically connected to the power supply plug of the support base such that when a cable is connected to both the second storage device and the extension socket, power of the second storage device can be supplied to the player.

15. The wireless digital music player as claimed in claimed 1, wherein the support base has an extension socket fitted thereon and electrically connected to the data socket thereof such that when a cable is connected to both a second storage device and the extension socket, music and audio data can be transferred from the second storage device to the portable storage device; the support base further having a switching member; the player being capable of being switched to a playing function with the switching member so as to play data stored in the portable storage device; the player being capable of being switched to a saving function with the switching member so as to allow data to be transferred from the second storage device to the portable storage device.
